(19) United States
(12) Patent Application Publication
(10) Pub. No.: US 2009/0309608 A1
(43) Pub. Date: Dec. 17, 2009

(54) Diagnostic methods for self-healing cables

(75) Inventors: Dryver Huston, South Burlington, VT (US); Bernard Tolmie, Grand Isle, VT (US)

Correspondence Address: OPTICUS IP LAW, PLLC, 7791 ALISTER MACKENZIE DRIVE, SARASOTA, FL, 34240, US

(73) Assignee: UNIVERSITY OF VERMONT AND STATE AGRICULTURE COLLEGE

(21) Appl. No.: 12/462,374

(22) Filed: Aug. 3, 2009

Related U.S. Application Data
(63) Continuation-in-part of application No. 11/803,430, filed on May 15, 2007, now Pat. No. 7,569,774.

(51) Int. Cl. G01R 31/08

(52) U.S. Cl. 324/527

(57) ABSTRACT

Self-healing diagnostics methods are disclosed. One of the methods involves determining whether a self-healing cable has at least one self-healed region and includes transmitting an outgoing test signal down the self-healing cable and measuring the return test signal. The method also includes comparing the measured return test signal to an ideal return signal associated with the same type of self-healing cable that has no self-healed regions to determine whether the self-healing cable has at least one self-healed region. A database of return signals based on different types of self-healed regions formed by different types of damaging conditions is also used to characterize the return test signal and thus the type of self-healed region present in the cable.

### CROSS-REFERENCE TO RELATED APPLICATIONS

This application is a continuation-in-part of U.S. patent application Ser. No. 11/803,430, entitled “Self-healing cable for extreme environments,” filed on May 15, 2008, which issued as U.S. Pat. No. 7,569,744 on Aug. 4, 2009, and which application and patent are incorporated by reference herein.

This application is related to U.S. patent application Ser. No. 11/362,611, entitled “Self-healing cable apparatus and methods,” filed on Feb. 27, 2006, and which issued as U.S. Pat. No. 7,302,145 (hereinafter, “the '145 patent”), which patent has a common inventor and assignee as the present application, and which patent is incorporated by reference herein.

### STATEMENT OF GOVERNMENTAL SUPPORT

This invention was made in part with U.S. Government support under Cooperative Agreement No. NCC5-581 by Vermont's NASA EPSCoR Program and under NSF EPS Grant No. 0236976 by Vermont's NSF EPSCoR Program. The U.S. Government therefore has certain rights in this invention.

### BACKGROUND OF THE INVENTION

1. Field of the Invention

The present invention relates generally to self-healing cables for a variety of applications (e.g., electrical, optical, fluid, gas, etc.), and particularly to methods of diagnosing self-healing cables.

2. Technical Background

Cable failures are a major concern in high-performance engineered systems such as cars, airplanes, boats, submarines, spacecraft, nuclear power plants, buildings, etc. For example, cabling problems on commercial and military aircraft have been implicated as the cause of accidents. Cable failures can occur for a number of reasons, such as the result of physical chafing, vibration, and wires in bundles rubbing against each other. These actions are examples of damaging forces that can cause a self-healing cable to become cracked and broken, and in the case of electrical wiring may cause shorts, sparks, incorrect signals, fire, and arcing, among many other possible electrical failures. While all cabling suffers from these hazards, self-healing cabling can reduce the level of hazard by autogeneously recovering some of the insulation capabilities following damage.

Even though self-healing cable failure poses a significant safety hazard reduction in many applications, self-healing cable inspection and repair remains difficult and expensive, especially when a self-healing event has occurred. Hidden self-healing cable damage is difficult to locate, and the self-healing cable inspection process itself can itself cause self-healing cable damage. In this regard, a self healing event prevents catastrophic cable failure but remains undetected even though the original cable insulation has been compromised. Self-healing event cable replacement is often quicker than diagnosis and repair if and only if it is obvious a self-healing event occurred.

Of particular concern is self-healing cable failure in extreme environments, i.e., environments that experience extremes in one or more environmental characteristics, such temperature, pressure, and acceleration (particularly vibration). Such extreme environments occur, for example, in aviation and aeronautical applications. Not only does an extreme environment exacerbate self-healing cable failure issues, it also prevents most types of self-healing cables developed for use the utility and construction industries from operating properly. For example, U.S Patent Publication No. US2005/0136257 to Easter discloses a self-healing cable that has a water-swellable composition surrounding a conductor. When the self-healing cable is damaged, the water-swellable material reacts with water and seals the breach in the self-healing cable. However, this approach will not work in an extreme environment wherein the temperature can swing below the freezing point of water. Nor will it work in an environment where liquid water is absent.

Another issue related to cabling used in extreme environments is that such cabling needs to satisfy higher design standards and specifications. For example, aviation and aerospace cabling needs to satisfy U.S. Military Specification No. 22759, which has a variety of requirements, such for temperature (down to −55° C.), extreme bending, dielectric strength, etc. Thus, any self-healing cable used in an extreme environment needs to perform at or near such stringent requirements. The prior art self-healing cables are typically suitable for select environments that do not experience a wide variation in environmental conditions experienced in extreme environments and so are unsuitable for extreme environment applications. The self healing method is only a temporary ‘fix’ to prevent catastrophic failure but is not a permanent substation of the continuous structural integrity or homogeneity of the original cable insulation.

Beyond simply performing self-healing, it is useful to know if and when a self-healing event has taken place in a self-healing cable so that the cable can be inspected and if necessary replaced. For example, a self-healing cable as used in machinery may provide adequate performance after it has undergone a self-healing event but the strict requirements of certain machinery (e.g., aircraft) may require that the cable nevertheless be replaced with a new cable.

### SUMMARY OF THE INVENTION

The present invention is directed to methods of determining (e.g., detecting) whether one or more self healing events occurred in a self-healing cable. The methods can be applied in situ and in real time, or applied later in time, e.g., after the self-healing cable has been removed from an apparatus such as an aircraft.

An aspect of the present invention is a method of determining whether a self-healing cable has at least one self-healed region. The method includes transmitting an outgoing test signal down the self-healing cable and measuring a return test signal from the self-healing cable. The method also includes comparing the measured return test signal to an ideal return signal associated with the same type of self-healing cable that has no self-healed regions to determine whether the self-healing cable has at least one self-healed region

Another aspect of the invention involves the above method and further includes creating a return signal database by measuring return signals for different self-healing cables having different self-healed regions formed under different damaging conditions. The method further includes comparing the measured return test signal to the measured return signals in the return signal database to characterize the measured return test signal.

Another aspect of the invention is a method of determining whether a self-healing cable has a localized self-healed region. The method includes providing a self-healing cable having a protective cover that includes at least one reactive layer configured to respond to a damaging force to form the localized self-healed region. The method also includes transmitting an outgoing test signal down the self-healing cable, and measuring a return test signal from the self-healing cable. The method additionally includes comparing the measured return test signal to an ideal return signal associated with the same type of self-healing cable that has no self-healed region to determine whether the self-healing cable includes the self-healed region.

### BRIEF DESCRIPTION OF THE DRAWINGS

FIG. 1 is a cut-away partial side view of an example self-healing cable according to the present invention, showing a central conductor surrounded by an adaptive cover;

FIG. 2 is cross-sectional view of the self-healing cable of FIG. 1 as taken along the line 2-2, showing a generalized conductor surrounded by the adapted cover;

FIG. 3 is a cross-sectional view similar to FIG. 2, but illustrating an example embodiment wherein the conductor has two coaxial conductors, such as found in standard coaxial self-healing cable;

FIG. 4 is a cross-sectional view similar to that of FIGS. 2 and 3, but illustrating an embodiment wherein the self-healing cable includes a number of conductors each having a surrounding insulating layer;

FIG. 5 is a cross-sectional view similar to FIG. 4, but illustrating an embodiment wherein the self-healing cable is a ribbonized self-healing cable bundle having a square cross-section;

FIG. 6 is a schematic diagram of an example self-healing cable manufacturing tool used to make commercial cabling and that is suitable for fabricating the self-healing cable of the present invention;

FIG. 7 is a schematic side view of an example embodiment of the self-healing cable of the present invention in a first stage of fabrication using tool the tool of FIG. 6, wherein a radially compressive/expansive (C/E) foam layer is formed around the conductor via a braiding operation;

FIG. 8 is an end-on view of the self-healing cable of FIG. 8, illustrating the radial direction r and the radial compressive and expansive force components associated with the compressive/expansive (C/E) layer;

FIG. 9 is a schematic side view of an example embodiment of the self-healing cable of the present invention in a second stage of fabrication using the tool of FIG. 6, wherein a tape layer is used to axially and/or radially compress the underlying C/E foam layer;

FIG. 10A is a schematic cut-away side view of an example embodiment of the self-healing cable of the present invention in a third and final stage of fabrication using the tool of FIG. 6, showing the radial compressive and expansive force components associated with the compressive/expansive (C/E) layer that exist along the length of the self-healing cable;

FIG. 10B is similar to FIG. 10A but shows the axial compressive and expansive force components associated with the compressive/expansive (C/E) layer that exist along the length of the self-healing cable;

FIG. 11 is a cross-sectional view of the self-healing cable of FIG. 10 taken along the line 11-11, and showing an external damaging force acting on the self-healing cable over a limited area (region);

FIG. 12 is a cross-section view of the self-healing cable similar to that of FIG. 11, but illustrating a breach formed in the self-healing cable by the external force, and showing the localize release of the radial expansive force component in the C/E layer;

FIG. 13 is similar to FIG. 12, but showing the local expansion of a portion of C/E foam layer so that it protrudes into the breach to form a self-healed region;

FIG. 14 is a schematic side view of the self-healing cable of the present invention analogous to FIG. 12 that shows the breach formed by the damaging force along with the axial compressive and expansive forces that exist just prior to the formation of the breach;

FIG. 15 is a schematic side view similar to FIG. 14, but showing the localized axial and radial expansion of the C/E foam layer so that it protrudes into the breach to form a self-healed region;

FIG. 16 is a perspective view of a generic structure having a plate with an aperture formed therein and a self-healing cable of the present invention passing through the aperture, illustrating how a structure can subject a self-healing cable to a localized damaging force;

FIG. 17 and FIG. 18 are adapted from FIG. 5 and FIG. 6 of the '145 patent and illustrate an example self-healing cable, wherein the adaptive cover includes an inner reactive layer having frangible microcapsules;

FIG. 19 is a cross-sectional view of the coaxial self-healing cable of FIG. 3, and shows a self-healed region formed in the cable that impacts the outer conductor and the insulating layer and thus the electrical characteristics of the cable; and

FIG. 20 is a schematic diagram of an example system used to carry out a method of determining whether or not the self-healing cable includes any self-healed regions.

The various elements depicted in the drawing are merely representational and are not necessarily drawn to scale. Certain sections thereof may be exaggerated, while others may be minimized. The drawing is intended to illustrate an example embodiment of the invention that can be understood and appropriately carried out by those of ordinary skill in the art.

### DETAILED DESCRIPTION OF INVENTION

The present invention addresses the problem of repairing damage (e.g., wear, abrasion, chafing, puncture, slicing, heating, etc.) to various types of self-healing cables used in extreme environments by providing the self-healing cable with an adaptive covering that allows the self-healing cable to self-heal when damaged. The self-healing cable of the present invention serves to reduce the susceptibility to damage after installation, for instance, by employing an adaptive cover that protects the self-healing cable's core. Unlike prior art self-healing cables, the self-healing cable of the present invention is adapted to operate in extreme environments and use conventional self-healing cable manufacturing techniques.

Additionally, an aspect of the invention is directed to methods of diagnosing self-healing cables to determine whether they have undergone at least one self-healing event.

The term “extreme environment” as used herein means an environment that experiences a wide range of values for one or more environmental characteristic (e.g., temperature, pressure, humidity, acceleration (vibration), etc.).

The self-healing cables of the present invention are configured to satisfy some or all of the requirements (preferably, as many as possible) of U.S. Military Specification No. 22759, which for convenience are listed in the following table:

U.S. Military Specification No. 22759

| | |
|---|---|
| Temperature rating | 200° C. (392° F.) maximum conductor temperature. |
| Voltage rating | 600 volts (rms) at sea level. |
| Spark test of primary | Not required |
| insulation | |
| Impulse dielectric test | 6.5 kilovolts (peak), 100 percent test. |
| Insulation resistance | 5,000 megohms for 1000 ft (min). |
| Wrap test | Mandrel test required - no cracking. Dielectric test after mandrel wrap, |
| | 2500 volt (rms), 60 Hz |
| Blocking | 260 ± 2° C. (500 ± 3.6° F.). |
| Shrinkage | 0.125 inch max at 200 ± 2° C. (392 ± 3.6° F.). |
| Wicking | Size 22 through 12 - Procedure II; 2.0 percent (max) weight increase, |
| | 0.750 inch (max) dye travel. Size 10 through 0000 - No requirement. |
| Low temperature | Bend temperature −65 ± 2° C. (−85 ± 3.6° F.). |
| (cold bend) | Dielectric test, 2500 volts (rms), 60 Hz. |
| Thermal shock | Oven temperature, 200 ± 2° C. (392 ± 3.6° F.). |
| | Max change in measurement - |
| | Sizes 22 through 12 - 0.060 inch. |
| | Sizes 10 through 8 - 0.100 inch. |
| | Sizes 6 through 0000 - 0.125 inch. |
| Flammability | Post-flame dielectric test required, 600 volts (rms), 60 Hz |
| Life cycle | Oven temperature 313 ± 2° C. (595.4 ± 3.6° F.). |
| | Dielectric test, 2500 volts (rms), 60 Hz |
| Dielectric test after | 2500 volts (rms), 60 Hz. |
| immersion | |
| Humidity resistance | 5,000 megohms for 1000 ft, min insulation resistance after humidity |
| | exposure |
| Surface resistance | Sizes 22 through 12 - 500 megohm-inches (min), |
| | initial and final readings. |
| | Sizes 10 through 0000 - No requirement. |
| Smoke: | 313° C. (595.4° F.). |
| Acid resistance | Required. Dielectric test, 2500 volts (rms), 60 Hz. |
| Color | In accordance with MIL-STD-104, Class 1; white preferred. |
| Color striping or banding | 50 cycles (100 strokes) (min), 125 grams weight. |
| durability | |
| Identification durability | 50 cycles (100 strokes) (min), 125 grams weight. |

In the present invention, the term “conductor” is used broadly and includes electrical conductors (e.g., self-healing cables, metal wiring, etc.), optical conductors (e.g., optical fibers, optical fiber self-healing cables, optical waveguides, etc.), fluid (i.e., gas, liquid, vacuum) conductors (e.g., transfer tubing), and the like.

In addition, the term “adaptive cover” is used to define some or all of those parts of the self-healing cable other than the conductor that contribute to the self-healing properties of the self-healing cable, and that includes at least one reactive layer. Here, the “reactive layer” is one or more layers that respond to a damaging force by changing form in a manner protects the conductor and thereby provides “self-healing.” Further, the “reactive layer” is one that is adapted to provide self-healing in extreme environments, rather than simply in select environments. However, the adaptive self-healing layer is generally not intended to become a permanent replacement to the original cable insulation.

Further, the term “self-healing cable” is used in the broad sense to describe a conductor in combination with the adaptive cover of the present invention, as described below.

Also, the term “damage” is used herein in the general sense and can be any type of harm to the self-healing cable caused by a force, referred to herein as a “damaging force,” of sufficient nature and strength to put the self-healing cable's normal operation at risk. Examples of a damaging force include such physical actions as wearing, abrasion, chafing, puncturing, slicing, tearing, melting, cracking, bending, electrical arcing, radiation, hydrolysis, etc., acting either alone or in combination.

In addition, a “self-healing event” is defined as an occurrence where the self-healing cable reacts to a damaging force on the cable insulation (adaptive cover) in a manner that causes the adaptive covering (described below) to change its properties at one or more localized regions to inhibit further damage to the self-healing cable.

### Self-Healing Cable Apparatus

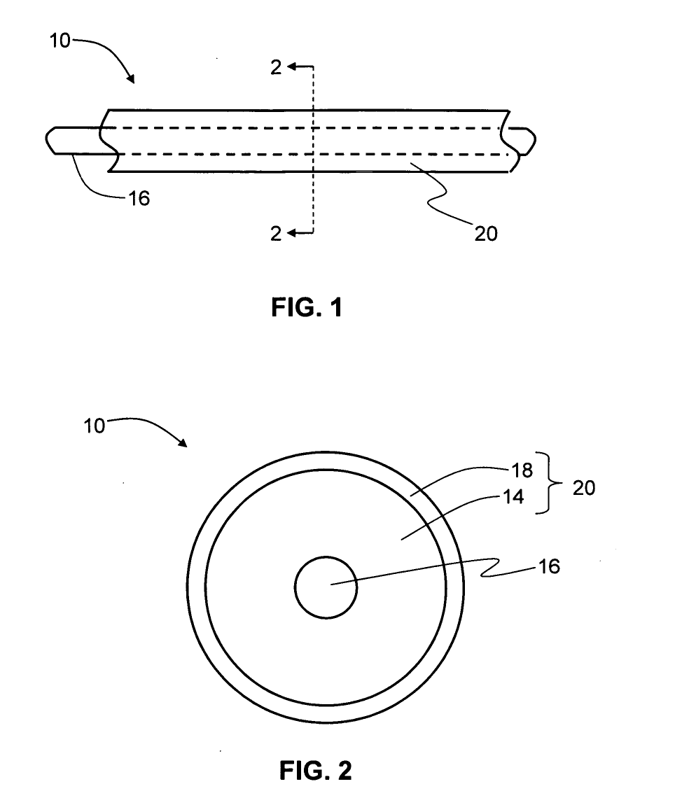

FIG. 1 is a side view of an example self-healing cable 10 according to the present invention. FIG. 2 is face-on view of self-healing cable 10 as viewed in direction of arrows 2-2 in FIG. 1. Self-healing cable 10 includes a generic example of a conductor 16 surrounded by an adaptive cover 20 that engages the conductor. In an example embodiment, adaptive cover 20 includes at least one reactive layer 14 (discussed below) that comprises a material that protects conductor 16 in response to a damaging force, and a protective cover 18 that surrounds the reactive layer.

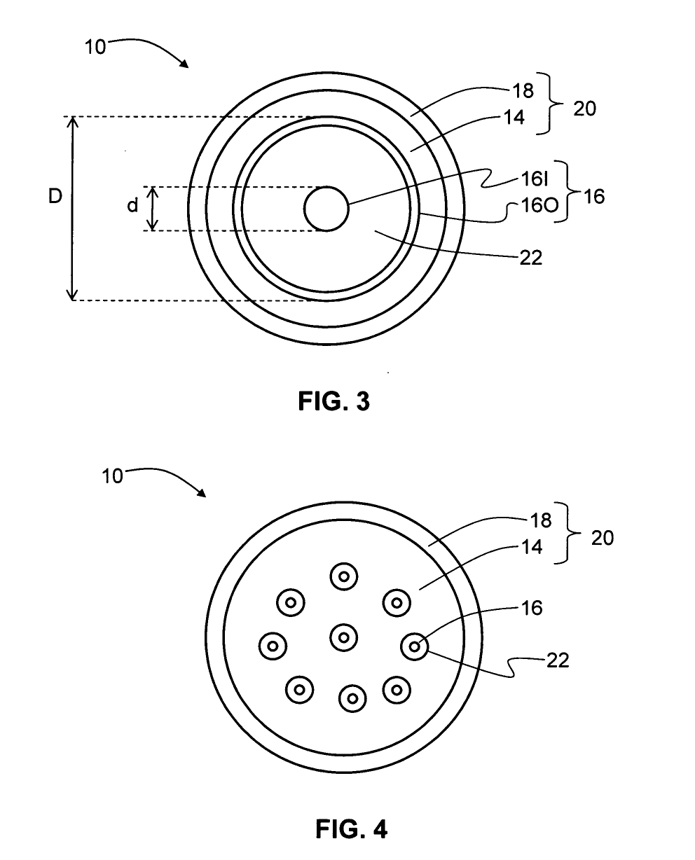

The present invention is not limited to centralized conductor configurations. For example, FIG. 3 is a cross-sectional view of an example embodiment of self-healing cable 10 similar to FIG. 2, wherein conductor 16 has two coaxial conductors, an inner conductor 16I and an outer conductor 16O, with an insulating layer 22 therebetween, such as found in standard coaxial self-healing cable.

FIG. 4 is a cross-sectional view of another example embodiment of self-healing cable 10 similar to FIGS. 2 and 3, wherein the self-healing cable includes a number conductors 16 having an insulating layer 22 surrounding the conductor.

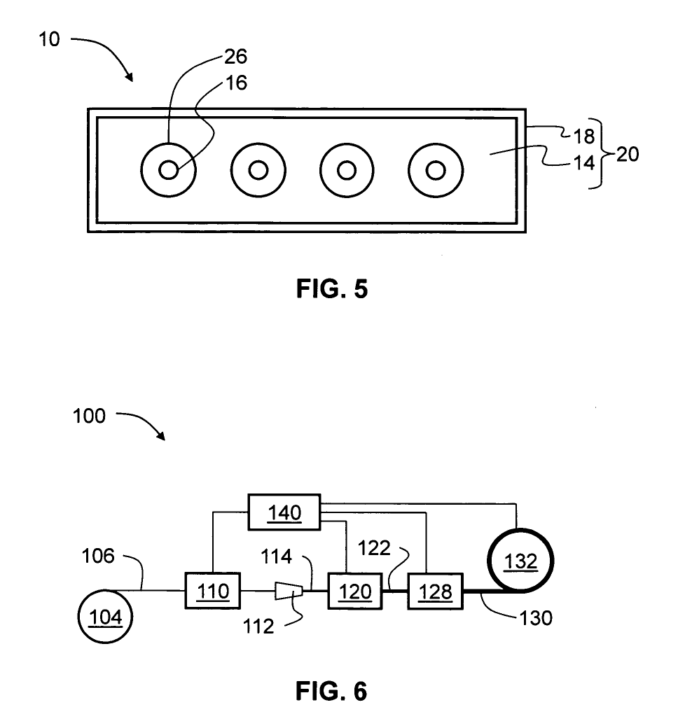

FIG. 5 is a cross-sectional view of another example embodiment of self-healing cable 10 similar to FIG. 4, but wherein the self-healing cable is a ribbonized self-healing cable bundle having a square cross-section.

In an example embodiment, adaptive cover 20 is adapted to locally react to damage to the self-healing cable in a manner that locally protects the conductor in and around the area of damage so that the self-healing cable can operate safely, preferably at or near its normal operating conditions even in an extreme environment. In an example embodiment, adaptive covering 20 locally changes its properties to inhibit further damage to the self-healing cable, particularly conductor 16. The self-healing is kept local (i.e., substantially limited to the region of damage) by the structure of the self-healing cable, as explained below.

Certain cabling applications have requirements for ease of installation and routing of self-healing cables through complex geometries. Such requirements often dictate that the self-healing cable be flexible during the installation process. This prohibits the use of very hard, durable coverings. However, after installation, the conductors can be subject to a damaging force by virtue of ordinary use or through extraordinary circumstances (e.g., an accident).

In one example embodiment of self-healing cable 10, adaptive covering 20 extends substantially over an entire length of the self-healing cable, so that the self-healing property of the self-healing cable is present over most if not all of the self-healing cable's length. In another example embodiment, adaptive covering extends over one or more portions of the self-healing cable's length. This latter example embodiment is suitable, for example, in situations where the self-healing cable 10 will experience damaging forces at known locations when the self-healing cable is installed in a structure, e.g., such as threading the self-healing cable through regularly spaced plates or bulkheads.

### Commercial Manufacturability of the Self-Healing Cable

As mentioned above, an advantage of self-healing cable 10 of the present invention is that it can be manufactured using commercially available cable manufacturing tools. FIG. 6 is a schematic diagram of an example self-healing cable manufacturing tool 100 used to make commercial cabling. An example tool 100 is available from Eagle Co., No. 252, Huzhou Lu, Jiaozhou City, Qingdao, China, and described at www.eagleco.en.alibaba.com. Tool 100 includes a conductor spool 104 that stores a wire 106 (which is one form of conductor 16). Wire 106 is feed into a braiding apparatus 110, which forms a braided layer (usually, other wires) around central wire 106. A compression cone 112 is used to compress the braided layers around wire 106, thereby forming a braided wire 114. The braided wire proceeds to a tape-wrap apparatus 120, which wraps an insulating tape around the braided conductor to form a tape-wrapped braided wire 122. The tape-wrapped braided wire 122 then proceeds to a coating apparatus 128, which coats the tape-wrapped braided conductor with a extruded protective outer coating, such as TEFLON, to form the final self-healing cable 130. A motorized take-up spool 132 receives and stores self-healing cable 120. Tool 100 is controlled by a controller (e.g., a computer) 140 that is operably connected to braiding apparatus 110, tape-wrap apparatus 120, coating apparatus 128 and take-up spool 132, and that controls the overall operation of the tool.

### Preferred Embodiment of the Self-Healing Cable

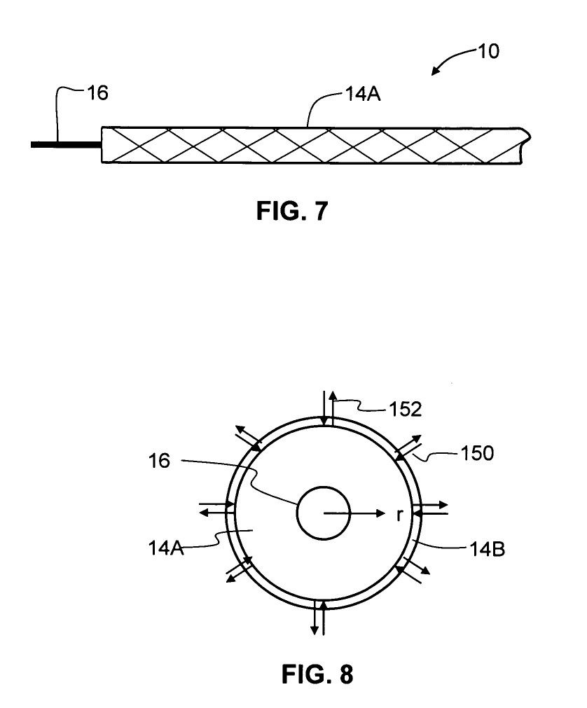

FIG. 7 is a schematic side view of an example embodiment of self-healing cable 10 of the present invention in a first stage of fabrication. In an example embodiment, tool 100 is used, wherein conductor 16 is stored on spool 104. In FIG. 7, a first reactive sub-layer 14A that is or otherwise includes a radially and/or axially compressible/expandable (C/E) foam is provided to surround conductor 16, e.g., wrapped around the conductor using braiding apparatus 110 of tool 100. Sub-layer 14A is thus referred to hereinafter as “C/E foam layer 14A.” C/E foam layer 14A is insulating and of the type that does not significantly change its properties in extreme environments. In an example embodiment, C/E foam layer exceeds, meets, or comes close to meeting current military performance specifications, such as the above-described MIL-W-22759 specifications or the equivalent or updated version(s) thereof.

In an example embodiment, C/E foam layer 14A is or includes a fluoropolymers, such as viscoelastic polytetrafluoroethylene (PTFE) foam (PTFE is better known under its trademarked name TEFLON, a trademark of Dupont Corporation). Such foam is available from American Micro Industries, Inc., and comes in sheets from 0.125 inches thick to 2.0 inches thick, and have a thermal range of −240° C. to 205° C. (400° F. to +400° F.). Other example fluoropolymers for C/E foam layer 14A are PFA and FEF. Other suitable materials for C/E foam layer 14A include viscoelastic polyurethanes and aromatic high-temperature polymers, such as PI, PPO, PPS (Polyphenylene sulphide), poly-etheretherketone (PEEK). One particular viscoelastic polyurethane suitable for use as a material for C/E foam layer 14 is the polyurethane-based memory foam TEMPUR, a trademark of Tempur-Pedic, Inc., of Lexington, Ky. Of the above-identified materials, PEEK, PPS and PTFE are the preferred materials based on U.S. Military Specification No. 22759 as set forth above.

FIG. 8 is an end-on view of self-healing cable 10 of FIG. 7, illustrating the radial direction r. With reference to FIG. 8, C/E foam layer 14A is radially compressible when subject to a radial compressive force component 150, as illustrated by radially inward-pointing arrows. Here, the compressive force 150 is provided by an outer layer 14B, as described below. In an example embodiment, C/E foam layer is axially and/or radially compressible, and is preferably both axially and radially compressible. Here, only the radial compressive force component 150 is shown by way of illustration. The radial compression of C/E foam layer 14A is such that energy is stored in the layer and results in a radial expansive force component 152, illustrated by radially outward-pointing arrows. Thus, compressive force 150 needs to be continually applied to the C/E layer to maintain the layer in a compressed state (i.e., to counterbalance expansive force component 152). Release of compressive force 150 allows C/E foam layer 14A to expand back to (or nearly to) its uncompressed state via an expansion force component 152. In an example embodiment of the first fabrication state illustrated in FIG. 7, C/E foam layer 14A is substantially uncompressed or only partially radially compressed by the braiding process.

Once C/E foam layer 14A is applied to conductor 16, it may need time to cure, which determines the rate at which self-healing cable 10 moves through tool 100. After self-healing cable 10 passes through braiding apparatus 110, the self-healing cable passes through compression cone 112, which further radially compresses C/E layer 14A, but preferably not to the point where it is fully compressed.

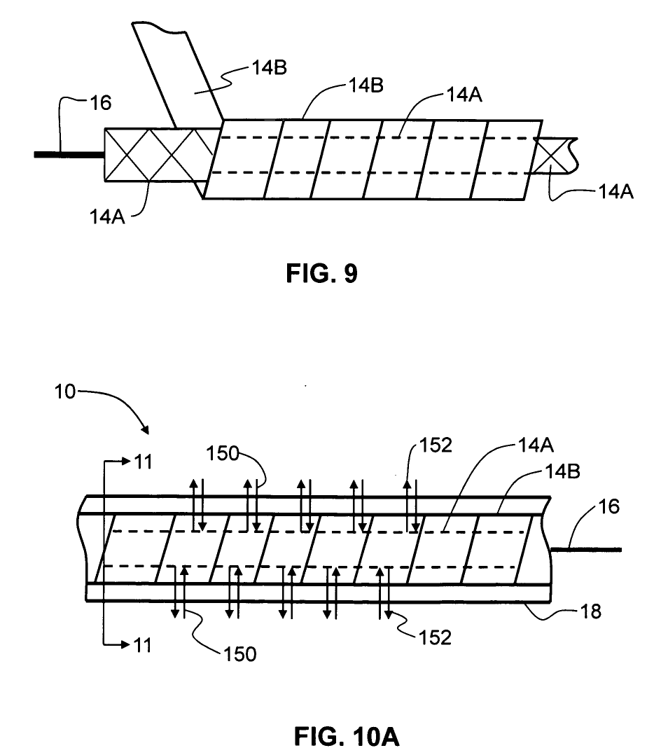

FIG. 9 is a schematic side view of self-healing cable 10 in a second stage of fabrication, wherein a second sub-layer 14B of reactive layer 14 is formed by tape wrap apparatus 120 of tool 100 in a manner that radially and axially compresses C/E foam layer 14A completely or nearly completely. Sub-layer 14B is thus referred to hereinafter as “tape layer 14B.” In a preferred example embodiment, tape layer 14B is or includes TEFLON tape, and tape wrap apparatus 110 is modified to accommodate such tape if necessary. Tape layer 14B is strong enough to provide the necessary compressive forces, yet is thin enough so that it allows for C/E foam layer 14A to reside relatively close to self-healing cable outer jacket 18 to effectuate the self-healing process very soon after the self-healing cable integrity is breached.

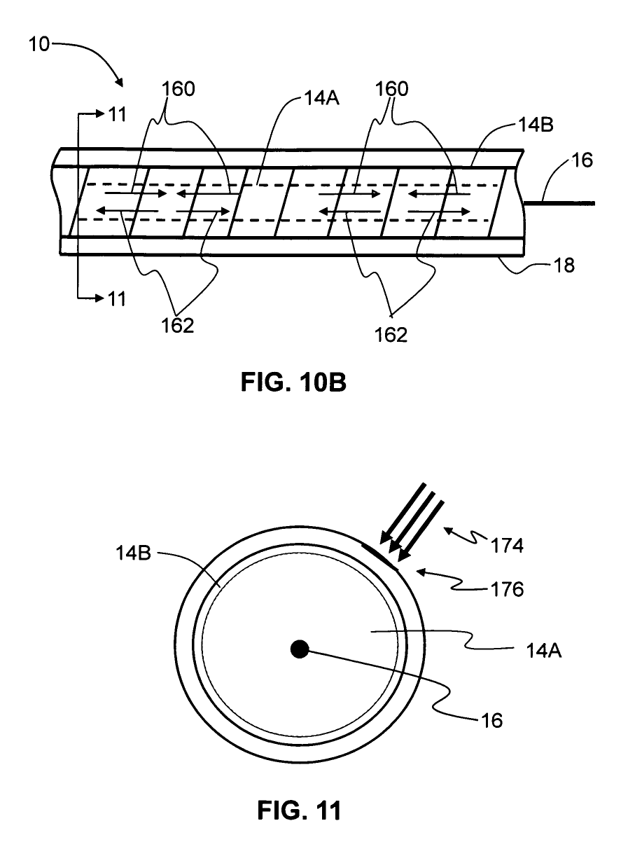

FIGS. 10A and 10B are schematic side views of a portion of self-healing cable 10 in a third and final stage of fabrication, wherein the tape-wrapped self-healing cable of FIG. 9 is sent to coating apparatus 128 of tool 100, which coats the tape-wrapped self-healing cable with an extruded protective outer coating (jacket) 18. In an example embodiment, the material used for outer jacket 18 is TEFLON.

FIG. 10A shows the equilibrium between the radial compression and expansive forces 150 and 152 due to the compression of C/E foam layer 14A by tape layer 14B (as well as from outer coating 18), and the expansion force associated with the potential energy stored in C/E foam layer. The potential energy is released when the compressive force is released.

FIG. 10B shows the equilibrium between the axial compression and expansive forces 160 and 162 due to the axial compression of C/E foam layer 14A by tape layer 14B (as well as from outer coating 18), and the axial expansion force associated with the potential energy stored in C/E foam layer. The potential energy is released when the compressive force is released. Axially compressive force 160 is created, for example, by applying tape layer 14B to C/E foam layer 14A in a manner that pulls the underlying C/E foam layer in the axial direction. This can be done for example, by bringing the tape layer 14B into contact with C/E foam layer 14A and then both radially and axially tightening the tape layer while winding the tape layer around the underlying C/E foam layer. In a preferred example embodiment, tape layer 14B is wound around C/E foam layer 14A in a manner that axially compresses the C/E foam layer in both axial directions so that each point in the C/E foam layer has a balancing expansive force that is axially directed in opposite directions-much like compressing a spring from both sides. FIG. 11 is a cross-sectional view of the final self-healing cable 10 of FIGS. 10A and 10B taken along the line 12-12, and showing an external damaging force component 174 acting on the self-healing cable over a limited area (region) 176 (shown as a bold line for the sake of illustration).

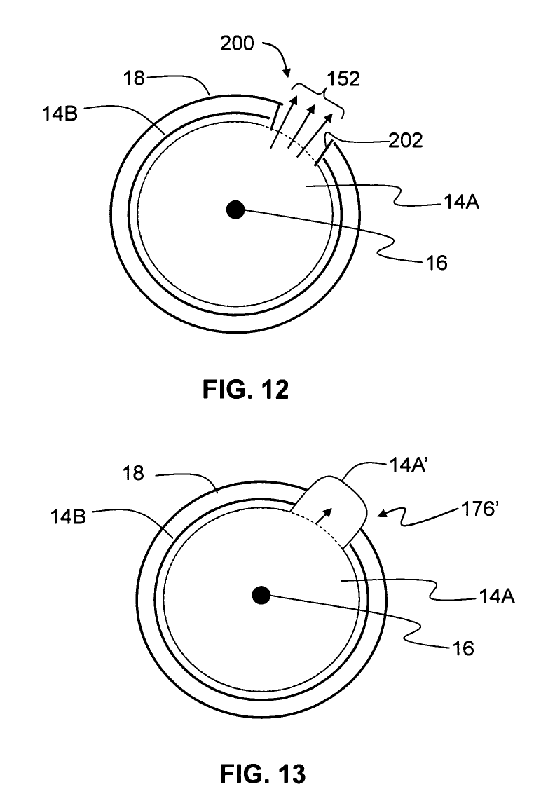

FIG. 12 is a cross-section view of self-healing cable 10 similar to that of FIG. 11, but illustrating the self-healing cable having a breach 200 formed in outer jacket 18 and tape layer 14B due to damaging force component 174. Breach 200 has an inner edge 202 formed by outer jacket 18 and tape layer 14B. FIG. 12 also shows the localized radial expansive force component 152 of C/E foam layer 14A that is “released” when the counterbalancing compressive force 150 is removed. The self-healing cable of FIG. 12 is shown just prior to C/E layer 14A reacting to expansion force component 152 for the sake of illustration.

FIG. 13 is similar to FIG. 12, but shows the local expansion of a portion 14A′ of C/E foam layer 14A caused by expansive force component 152 that causes portion 14A′ to protrude into and through breach 200. This causes region 156 to become a self-healed region 176′. Edge 202 of breach 200 serves to keep self-healed region 176′ localized, since the undamaged portion of these layers provide a compressive force on the remainder of C/E foam layer 14A. This also allows for multiple self-healed regions 176′ to be formed in self-healing cable 10, wherein one self-healed region does not substantially affect another such region. In the case where one self-healed region is close enough to interact with an adjacent self-healed region, the two self-healed regions may coalesce to form a single self-healed region.

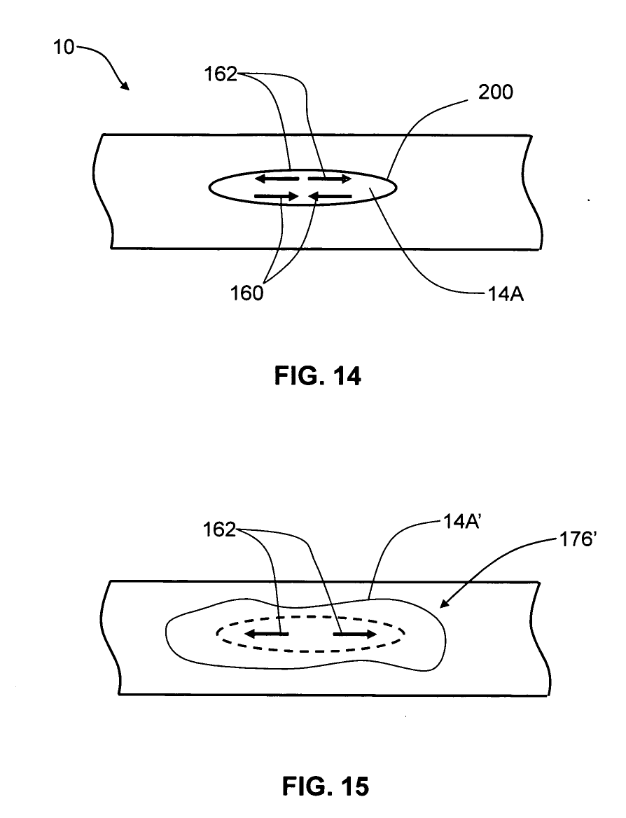

FIG. 14 is a schematic side view of a section of self-healing cable 10 showing breach 200 immediately after it is formed in the cable and shown just prior to the exposed C/E layer 14A reacting to axial expansive force components 162. The balance between the axial compression and expansive force components 160 and 162 are shown. FIG. 15 is similar to FIG. 14 and shows how the axial expansive force components 162 act to cause a portion 14A′ of C/E layer 14A to axially expand to fill and cover breach 200 and form self-healed region 176′. In a preferred embodiment, both radial and axial expansive forces 152 and 162 act together to fill and cover breach 200. For a given type and orientation of breach 200, however, one these two expansive forces is likely to play a greater role than the other.

Structure with Incorporated Self-Healing Cable

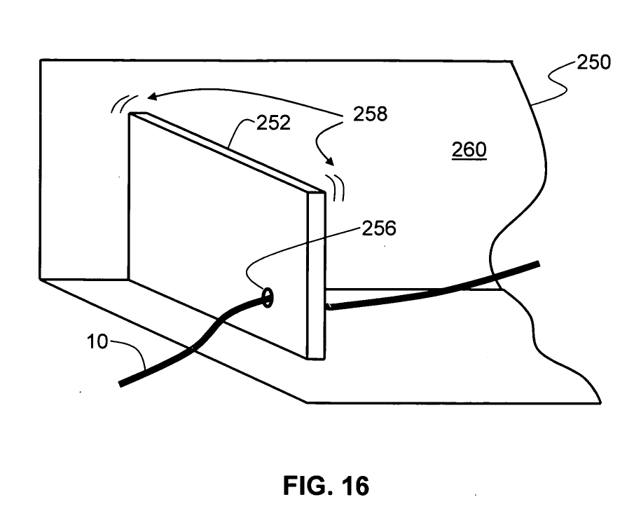

FIG. 16 is a perspective partial view of a structure 250 that includes a plate 252 with an aperture 256 formed therethrough. Self-healing cable 10 of the present invention passes through aperture 256. Structure 250 is a generic example of an application wherein the self-healing cable of the present invention is incorporated into an apparatus and interacts with the structure in a way that subjects the self-healing cable to a localized damaging force. For example, structure 250 can be an airplane fuselage (the “apparatus”) and plate 252 can be an airplane bulkhead that vibrates because of normal aircraft operation. Self-healing cable 10 in this example may be a control self-healing cable that operably connects controls in the airplane cockpit to another part of the plane, such as the wing flaps or tail rudder. Hash marks 258 in FIG. 2 illustrate plate movement (e.g., vibration).

Structure 250 has an associated ambient environment 260 in which self-healing cable 10 resides. Ambient environment 260 is capable of extremes of at least one of environmental characteristic, such temperature, pressure, humidity, acceleration (including vibration, which is considered a form of micro-acceleration), etc. In an example embodiment, environment 260 is that associated with aerospace and aeronautical applications, including spacecraft (including satellites and space-borne scientific instrumentation), aircraft, rockets, missiles and the like.

Damage to self-healing cable 10 at the location of plate aperture 256 due to a damaging force in the form of plate vibration, for example, will ultimately cause a reaction in adaptive cover 20. The reaction results in the formation of a localized self-healed region (discussed below) in the self-healing cable that reduces the effect of the damage on the self-healing cable (and particularly the conductor) at the location where the damaging force occurs.

Because the self-healed region is local to the area of damage, the rest of the self-healing cable remains unaffected. For example, for a flexible self-healing cable 10, the unaffected parts of the self-healing cable remain flexible to facilitate such things as movement of the self-healing cable due to movement of control surfaces, or removal of the self-healing cable. Self-healing cables that do not remain flexible in non-damaged locations limit self-healing cable movement and tend to be difficult to remove and replace.

In an example embodiment, adaptive cover 20 is designed to provide a self-healed region of a desired relative size so that it protects an appropriate portion of self-healing cable 10 relative to the damaged area and/or where the damaging force is present. The self-healing nature of self-healing cable 10 eliminates the need for bulkhead grommets and other self-healing cable-protecting devices, and also contributes greatly to the safety of a wide variety of systems having self-healing cables that, when damaged, present a safety hazard.

In the case where conductor 16 is electrically conductive, the material(s) selected for the reactive layer of adaptive cover 20 are preferably selected to provide suitable electrical insulation for the conductor to prevent shorting, arcing, etc., when the self-healing cable is damaged and then self-healed. In an embodiment wherein the reactive layer includes multiple sub-layers, one, some or all of the layers may be electrically insulating.

In the case where conductor 16 is hydraulically or pneumatically conductive, the material(s) selected for reactive layer 14 of adaptive cover 20 preferably include those that can provide suitable sealing of the conductor to prevent leakage when the self-healing cable is damaged and then self-healed. Thus, in an embodiment wherein the reactive layer 14 includes multiple sub-layers, one, some or all of the layers may be sealant layers.

### Self-Healing Diagnostic Methods

An example embodiment of the present invention includes diagnostic methods to determine whether at least one self-healing event has taken place in the self-healing cable.

Typically, if the insulation in a cable fails, there is catastrophic failure of the conductor and a corresponding loss of signal, power or ground. A failure of the insulation can be caused, for example, by the conductor shorting to ground or to an adjacent conducting structure, or by a break in the conductor resulting in a discontinuity in the electrical circuit formed by the cable.

However, in self-healed diagnostic cable 10 of the present invention, under certain circumstances, no such catastrophic failure occurs. The self-healing event that forms the localized self-healed region 176′ allows the circuit associated with the self-healing cable to continue to operate, though protective cover 20 is altered in a manner that changes the electrical properties of the self-healing cable. Thus, self-healed region 176′ constitutes a “latent defect” that allows the cable to operate but with different electrical properties as compared to an “ideal” self-healed cable of the same type that has not undergone a self-healing event. In particular, self-healed region 176 has associated therewith a different dielectric constant, which results in different localized electrical capacitance and localized electrical impedance.

Visual inspection is one method of determining whether self-healing cable 10 has undergone a self-healing event. However, visual inspection of self-healing cable 10 is not always feasible because some or all of the self-healing cable may be routed to inaccessible regions. For example, cabling in aircrafts fuselages are strung through conduits, and underground cables or building cables are often routed through a plenum. Also, visual inspection is inefficient and is subject to error.

With reference again to FIG. 13, the local expansion of portion 14A′ of C/E foam layer 14A caused by expansive force component 152 causes portion 14A′ to protrude into and through breach 200. This causes region 156 to become a localized self-healed region 176′. The expansion is caused by the displacement of the self healed material with air. This local expansion of C/E foam layer has associated therewith a change in the dielectric constant by virtue of an increased amount of air in the C/E foam layer. Thus, from an electrical point of view, self-healed region 176′ represents a region of changed dielectric constant as compared to the surrounding regions.

At the initial state of damage, the breach in the insulation fills with air so that the breach has a lower dielectric constant than the undamaged surrounding insulation. Upon healing the insulation swells and fills the gap. The dielectric value of localized self-healed region 176′ is thus less than that of the undamaged insulation, but more than that of the air gap. If water is present these trends reverse since water has such a high dielectric constant. Thus, the dielectric constant associated with self-healed region 176′ can be increased or decreased relative to the undamaged self-healing cable 10. However, once self-healed region 176 is formed, it will typically have a lower dielectric constant than the undamaged insulation of the self-healing cable 10.

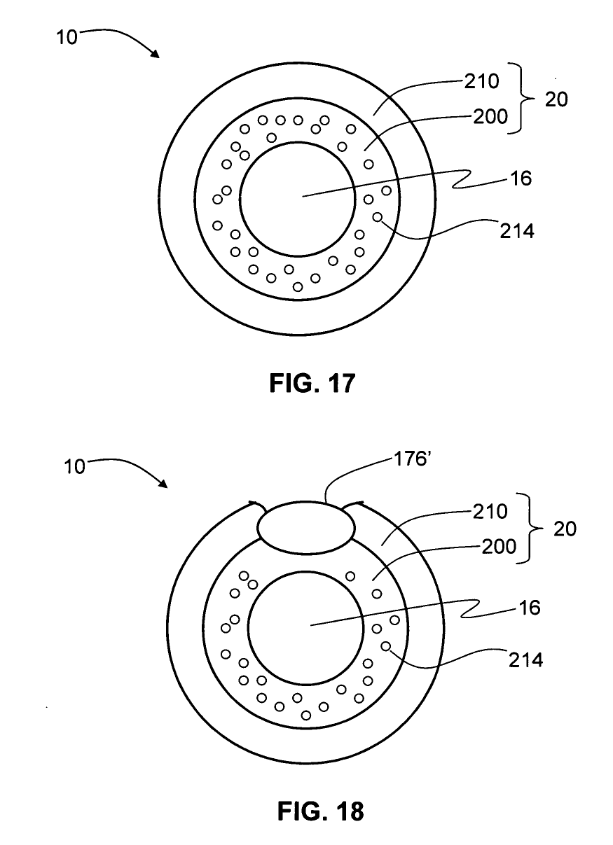

FIG. 17 and FIG. 18 are adapted from FIG. 5 and FIG. 6 of the '145 patent and illustrate another example self-healing cable 10 wherein adaptive cover 20 includes an inner reactive layer 200 surrounding conductor 16, and an outer protective layer 210 surrounding the curable inner layer. Reactive layer 200 includes a curable material along with frangible microcapsules 214, which contain a curing agent for the surrounding curable material in the inner curable layer.

In an example embodiment, reactive layer 200 includes a curable material, such as an epoxy resin, urethanes and silicones, etc., that is cured (i.e., toughened and/or hardened) by the corresponding curing agent (e.g., hardeners, oxidizers and catalysts, etc.), contained in microcapsules 214. Microcapsules 214 is made of a suitable material, e.g., urea-formaldehyde, that protects the curing agent and keeps it isolated from the surrounding curable material, but that is also frangible so that it breaks when subject to a damaging force sufficient to breach protective outer layer 210. Microcapsules 214 suitable for use with the present invention are well-known in the art.

In the operation of self-healing cable 10 of FIG. 17, when the local damage to the cable is sufficient to breach outer protective layer 210, curable inner layer 200 is exposed to the damaging force. This damage force—say, for example, abrasion or chafing from bulkhead aperture 256 of FIG. 16—continues to act on the exposed reactive layer 200, thereby rupturing microcapsules 214 present at the location of the cable damage. This releases the curing agent contained with the microcapsules into the curable material surrounding the ruptured microcapsules. This in turn locally cures the curable layer, resulting in a toughened and/or hardened localized self-healed region 176′, as illustrated in FIG. 18.

The formation of localized self-healed region 176′ in this manner not only modifies the overall dimensional and mechanical structure of self-healing cable 10 but also locally its electrical parameters, and specifically, it locally changes the dielectric constant of protective cover 20. This in turn changes the local electrical capacitance and local electrical impedance. In this example, microcapsules 214 are displaced by air in self-healed region 220. Since air has a dielectric constant of 1, the capacitance of the self-healing cable 10 at localized self-healed region 176′ changes relative to that of the remaining inactivated material in reactive layer 200 along the axial length of the self-healing cable.

The small changes in the dielectric constant at localized self-healed region(s) 176′ locally affect the complex value X_{C} of the electrical capacitance of the circuit formed by the self-healing cable 10, namely, X_{C}=½πFC, where C is the capacitance, which is a function of the value of the dielectric constant of the insulating portion of the cable and F is frequency in hertz. Thus, diagnostic systems capable of measuring a small capacitance change can detect this small change where the localized breach (i.e., the damaging event) has occurred.

With reference to FIG. 3 and a coaxial self-healing cable 10 shown therein, the design formula for the characteristic impedance Z₀ of a single coaxial cable is given by the equation:

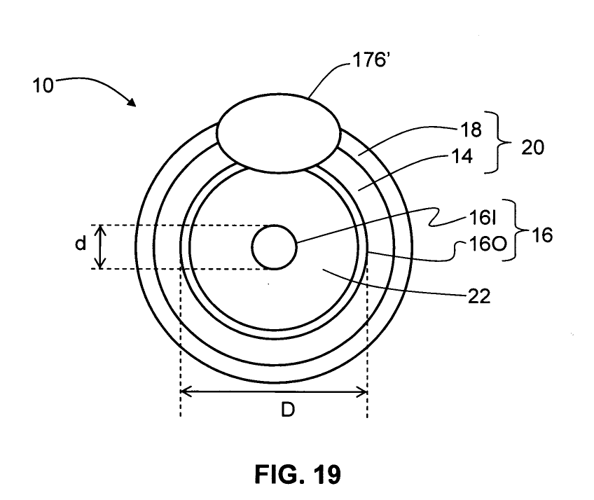

Z₀=(138/∈^{1/2})Log₁₀(D/d)

where ∈ is the dielectric constant (∈=1 for air), D is the inside diameter of the return or outer conductor 16O (e.g., a conductive metal tube or one or more braids), and d is the outside diameter of the inner conductor 16I. Thus, a localized change (at self-healed region 176′) in the characteristic impedance of a coaxial-type self-healing cable 10 occurs with a change in the outside dimensions of the cable as well as with a change in the dielectric constant associated with self-healed region 176′. FIG. 19 shows the coaxial self-healing cable 10 of FIG. 3 after adaptive cover 20 reacts to a damaging force and forms localized self-healed region 176′. The example of FIG. 19 illustrates how self-healed region 176′ can impact outer conductor 16O as well as insulating layer 22 between the inner and outer conductors.

The following materials have the following dielectric constants E: Air=1; Polyethylene (P/E) cellular foam=1.40 to 2.1; P/E (solid)=2.3; PTFE=2.1; cellular poly Tetrafluoroethylene (PTFE)=1.4; Fluorinated Ethylene Propylene (FEP)=2.1; cellular FEP=1.5; Butyl rubber=3.1; Silicon rubber=2.08 to 3.5. These dielectric constants E can change when subjected to the self-healing action of self-healing cable 10 at the site that the self-healing event has occurred.

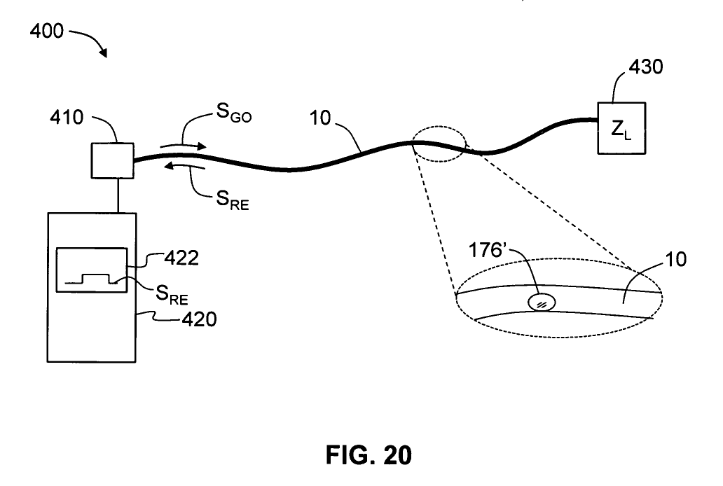

FIG. 20 is a schematic diagram of a generalized example system 400 used to determine whether self-healing cable 10 has experienced a self-healing event. System 400 includes a signal generator 410 operably connected to an oscilloscope 420 having a display 422. Self-healing cable 10 is connected at one end to the signal generator 410 and at another end to a device 430 having a load capacitance Z_{L}. Signal generator 410 generates an outgoing or “go” signal S_{GO} that serves as a test signal. This signal travels down self-healing cable 10 toward device 430. If “go” signal S_{GO} makes it to device 430, unless there is perfect impedance match, a portion of the signal reflects therefrom and becomes a return signal S_{RE}. The load capacitance Z_{L} of device 430 is typically known (or can be readily established) so that the characteristics of return signal S_{RE} are also known in the absence of any irregularities in self-healing cable 10. In one example, return signal SRE is zero when load impedance Z_{L} and the cable impedance Z_{C} are perfectly matched.

In one embodiment, example system 400 is configured in-situ so that the self-healing cable 10 can monitored in real time and within the environment or apparatus where the cable is installed. In another example embodiment, system 400 is used to measure a cable after it has been removed from the environment or apparatus where the cable was installed. Thus, in methods calling for providing self-healing cable 10, the “providing” of the cable includes delivering the cable to system 400 or accessing the cable with system 400 while the cable is arranged in an apparatus (e.g., in structure 250 as shown in FIG. 16, in an airplane fuselage, as discussed above, etc.).

In the case where self-healing cable 10 experiences a self-healing event and has at least one self-healed region 176′ as shown in the inset of FIG. 20, the return test signal S_{RE} will have characteristics that differ from the corresponding ideal self-healing cable (i.e., the same type of self-healing cable having no defects). Return signal S_{RE} is routed to oscilloscope 420 and displayed on a display 422, where the characteristics of the return signal can be observed. A change in the return signal characteristics from those expected from an undamaged self-healing cable indicate that a self-healing event took place in the self-healing cable.

In an example embodiment, various types of damaging conditions (e.g., different damaging forces) are applied to different types of self-healing cables 10 to generate various forms and numbers of localized self-healed regions 176′. These different self-healing cables are then measured using system 400 (preferably using a number of different load impedances Z_{L}) to create a database of characteristic return signal signatures for the different types of self-healed regions and self-healing cables. The return signals in the database are then compared to the return test signals, and their respective characteristics are used to determine whether a change in the electrical performance of the self-healing cable is due to the presence of one or more self-healed regions or is due to other causes, such as an internal short in the cable that did not initiate a self-healing response.

It will be apparent to those skilled in the art that various modifications and variations can be made to the present invention without departing from the spirit and scope of the invention. Thus, it is intended that the present invention cover the modifications and variations of this invention within the scope of the appended claims and their equivalents.

What is claimed is:

1. A method of determining whether a self-healing cable has at least one self-healed region, comprising:
a) transmitting an outgoing test signal down the self-healing cable;
b) measuring a return test signal from the self-healing cable; and
c) comparing the measured return test signal to an ideal return signal associated with the same type of self-healing cable that has no self-healed regions to determine whether the self-healing cable has at least one self-healed region

2. The method of claim 1, further comprising:
i) creating a return signal database by measuring return signals for different self-healing cables having different self-healed regions formed under different damaging conditions; and
ii) comparing the measured test return signal to the measured return signals in the return signal database to characterize the measured return test signal.

3. The method of claim 2, including varying a load impedance on the self-healing cable in act i) so that the database of return signals includes return signals based on different load impedances.

4. The method of claim 1, wherein the self-healing cable comprises a coaxial cable.

5. The method of claim 1, wherein the self-healing cable has an outer jacket and is formed by:
providing at least one conductor;
surrounding the at least one conductor with an axially and radially compressible/expandable (C/E) foam layer capable of expanding beyond the outer jacket; and
providing substantial axial and radial compressive forces to axially and radially compress the C/E foam layer to create opposing substantial axial and radial expansive forces in the C/E foam layer; and
providing an outer jacket over the axially and/or radially compressed C/E foam layer, so that when the outer jacket is locally breached in a manner that locally removes the axial and radial compressive forces, the axial and radial expansive forces cause the C/E foam layer to locally expand into the breach to form the self-healed region in said breach and that extends beyond the outer jacket.

6. A method of determining whether a self-healing cable has a localized self-healed region, comprising:
a) providing a self-healing cable having a protective cover that includes at least one reactive layer configured to respond to a damaging force to form the localized self-healed region;
b) transmitting an outgoing test signal down the self-healing cable;
c) measuring a return test signal from the self-healing cable; and
d) comparing the measured return test signal to an ideal return signal associated with the same type of self-healing cable that has no self-healed region to determine whether the self-healing cable includes the self-healed region.

7. The method of claim 6, wherein the at least one reactive layer includes a compressible/expandable (C/E) foam layer surround at least one conductor and configured to fill a breach formed by a localized damaging force to form the localized self-healed region

8. The method of claim 7, wherein the C/E foam layer axially and radially compressible/expandable and is adapted to maintain its compressibility and expandability over a temperature range between −65 and 260° C., and a pressure range of between 0 and 1 atmosphere, and wherein a tape layer is applied to the C/E foam layer so that it surrounds and axially and radially compresses the C/E foam layer so that the C/E foam layer includes substantial axial and radial expansive force components that are counterbalanced by substantial axial and radial compressive force components provided by the tape layer.

9. The method of claim 6, wherein providing the self-healing cable includes accessing the self-healing cable while the self-healing cable is operably configured in an apparatus.
